(19) United States
(12) Patent Application Publication
(10) Pub. No.: US 2018/0323567 A1
(43) Pub. Date: Nov. 8, 2018

(54) LASER BEAM GENERATION APPARATUS, LASER MACHINING DEVICE, AND LASER MACHINING METHOD

(71) Applicants: Yoshio WADA, Kanagawa (JP); Yasuhiro HIGASHI, Miyagi (JP); Shinsuke SHIBATA, Kanagawa (JP); Masayuki NUMATA, Miyagi (JP)

(72) Inventors: Yoshio WADA, Kanagawa (JP); Yasuhiro HIGASHI, Miyagi (JP); Shinsuke SHIBATA, Kanagawa (JP); Masayuki NUMATA, Miyagi (JP)

(21) Appl. No.: 15/773,763

(22) PCT Filed: Nov. 4, 2016
(86) PCT No.: PCT/JP2016/004813

§ 371 Date: May 4, 2018

(30) Foreign Application Priority Data
Nov. 12, 2015 (JP) 2015-222048
Sep. 16, 2016 (JP) 2016-181685

(51) Int. Cl. H01S 3/067; H01S 3/23; H01S 5/40; H01S 5/42; H01S 5/183; F21V 8/00

(52) U.S. Cl. CPC H01S 3/06758; H01S 3/2375; G02B 6/0006; H01S 5/423; H01S 5/183; H01S 5/4012

(57) ABSTRACT

A laser beam generation apparatus includes a light source section including a plurality of seed lasers each emitting laser light, an optical amplification section disposed to face the seed lasers of the light source section and configured to amplify the laser light emitted by the seed lasers and received at an incidence surface to output the amplified laser light from an emission surface, and a control unit configured to control each of the seed lasers of the light source section. The optical amplification section is configured to combine the laser light emitted by the seed lasers and output the combined laser light as a laser beam.

### TECHNICAL FIELD

The present disclosure relates to a laser beam generation apparatus, a laser machining device, and a laser machining method.

### BACKGROUND ART

It is known that an MOPA (master oscillator and power amplifier) laser beam generation apparatus includes a light source section (MO section) having high-speed modulation controllable semiconductor lasers as seed laser sources, and an optical amplification section (PA section) configured to amplify laser light from the low-power seed lasers and output a high-power laser beam. For example, see PTL 1, PTL 2, and PTL 3 listed below.

In the conventional MOPA laser beam generation apparatus, oscillating conditions, such as pulsed waveforms and repetition frequencies of the seed lasers, greatly contribute to the characteristics of the final output laser beam. In particular, a laser beam generation apparatus used for laser machining of a material requires high-speed modulation controllable seed lasers with the capability of setting complicated oscillating conditions to output a short pulse or burst pulse laser beam.

However, it is difficult for the conventional MOPA laser beam generation apparatus to control the oscillating conditions of the seed lasers with a high level of accuracy.

### CITATION LIST

### Patent Literature

### PTL 1: Japanese Patent No. 5595740

### PTL 2: Japanese Patent No. 5654649

### PTL 3: Japanese Patent No. 5713541

### SUMMARY

### Technical Problem

In one aspect, the present disclosure provides a laser beam generation apparatus which is able to provide a high level of flexibility in the oscillating conditions of laser light sources.

### Solution to Problem

In one embodiment, the present disclosure provides a laser beam generation apparatus including: a light source section including a plurality of seed lasers each emitting laser light; an optical amplification section disposed to face the seed lasers of the light source section and configured to amplify the laser light emitted by the seed lasers and received at an incidence surface to output the amplified laser light from an emission surface; and a control unit configured to control each of the seed lasers of the light source section, wherein the optical amplification section is configured to combine the laser light emitted by the seed lasers and output the combined laser light as a laser beam.

### Advantageous Effects of Invention

It is possible for the laser beam generation apparatus according to one embodiment to provide a high level of flexibility in the oscillating conditions of laser light sources.

The object and advantages of the invention will be realized and attained by means of the elements and combinations particularly pointed out in the claims. It is to be understood that both the foregoing general description and the following detailed description are exemplary and explanatory and are not restrictive of the invention as claimed.

### BRIEF DESCRIPTION OF DRAWINGS

FIG. 1 is a plan view illustrating an overall configuration of a laser beam generation apparatus according to an embodiment.

FIG. 2 is a diagram illustrating a configuration of a light source section of the laser beam generation apparatus illustrated in FIG. 1.

FIG. 3 is a block diagram illustrating a functional configuration of a control unit of the laser beam generation apparatus illustrated in FIG. 1.

FIG. 4 is a diagram for explaining a control operation of the control unit of the laser beam generation apparatus illustrated in FIG. 1.

FIG. 5 is a diagram for explaining a control operation of a modification of the laser beam generation apparatus illustrated in FIG. 1.

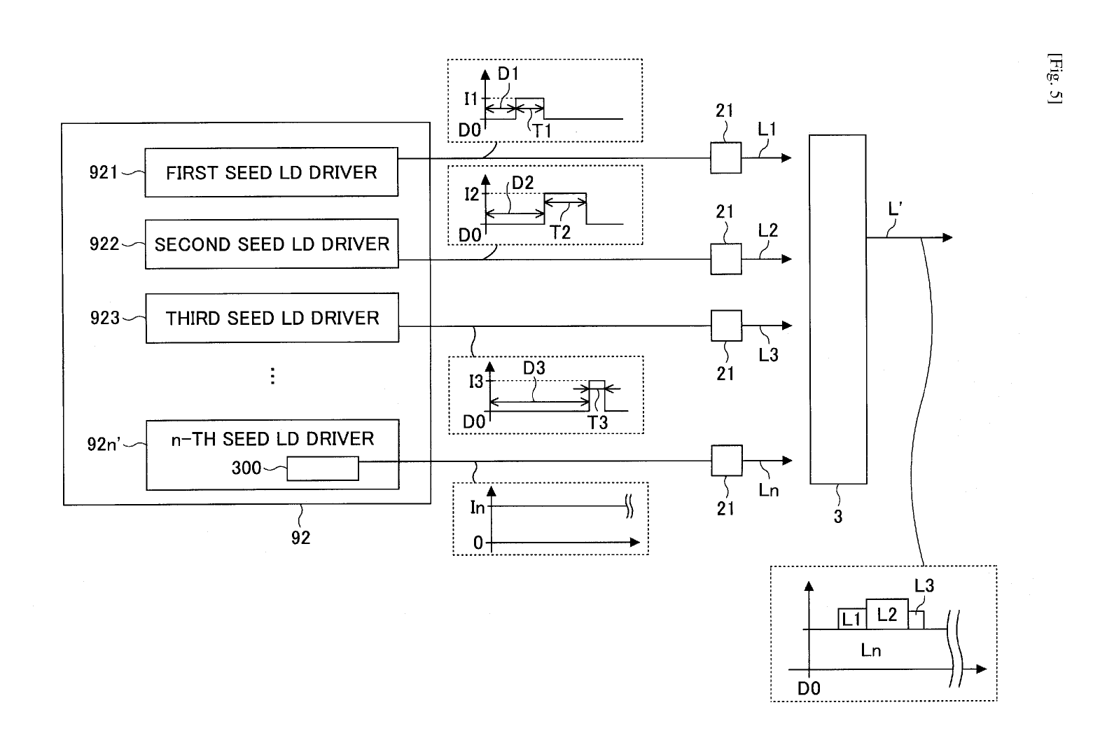

FIG. 6 is a diagram illustrating a comparative example of the laser beam generation apparatus.

FIG. 7 is a diagram illustrating a configuration of a laser machining device including the laser beam generation apparatus.

FIG. 8 is a flowchart for explaining a laser machining method performed by the laser beam generation apparatus.

### DESCRIPTION OF EMBODIMENTS

<Overview>

A laser beam generation apparatus according to an embodiment will be described with reference to the accompanying drawings.

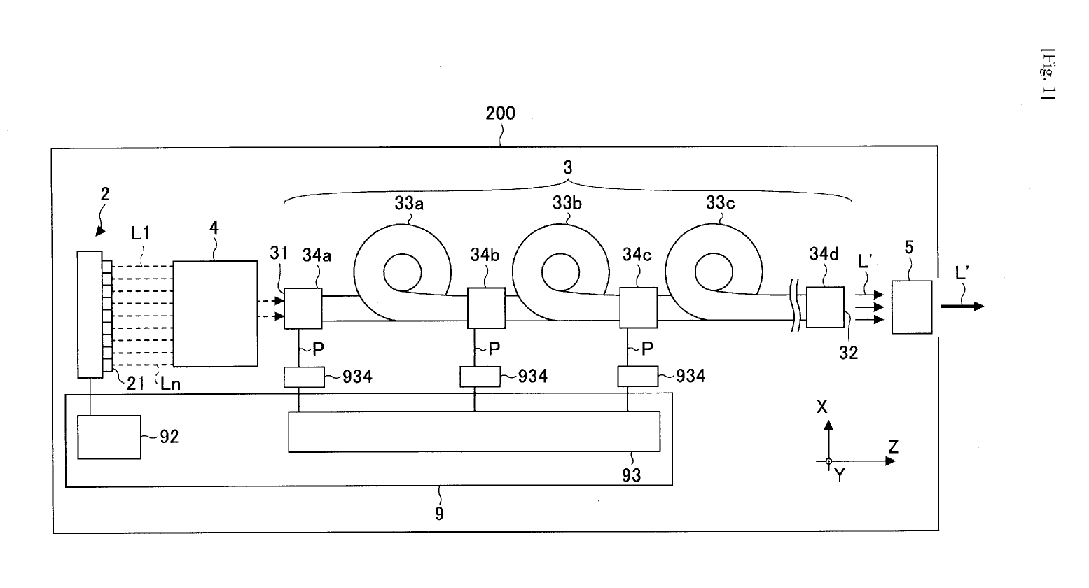

FIG. 1 illustrates an overall configuration of a laser apparatus 200 which is the laser beam generation apparatus according to the embodiment.

As illustrated in FIG. 1, the laser apparatus 200 includes a light source section 2 having n laser elements 21 (seed lasers L1 to Ln) configured to emit laser light, an optical amplifier 3 configured to amplify the laser light emitted by the seed lasers L1 to Ln of the light source section 2, and a control unit 9 configured to control the light source section 2 and the optical amplifier 3. In the following, when it is not necessary to specify a particular one of the seed lasers L1 to Ln, the seed lasers L1 to Ln are collectively referred to as a seed laser L.

The laser apparatus 200 further includes a first light-guiding optical system 4 configured to deflect the laser light from the seed laser L so that the deflected laser light enters an incidence surface 31 of the optical amplifier 3, and a second light-guiding optical system 5 configured to emit a laser beam L′ from an emission surface 32 of the optical amplifier 3 to a target object. In the following, it is assumed that a direction parallel to an optical axis of the seed laser L is represented by the +Z direction of an XYZ three-dimensional rectangular coordinate system.

The control unit 9 includes an oscillating condition control unit 92 configured to determine oscillating conditions of the seed laser L of the light source section 2, such as a pulsed waveform and a repetition frequency of the laser light, and an amplification condition control unit 93 configured to control amplification conditions for amplifying the laser light entering the optical amplifier 3. The control unit 9 may be implemented by a processor, such as a CPU (central processing unit), which is coupled to a memory. The above units 92 and 93 represent functions and units implemented by any of the elements and devices illustrated in FIG. 1, which are activated by instructions from the processor based on programs stored in the memory.

Operation of the laser apparatus 200 will be described briefly.

The seed laser L (each laser element 21) of the light source section 2 is caused to emit the laser light in the +Z direction according to the oscillating conditions determined by the oscillating condition control unit 92. The laser light from the seed laser L is deflected to the incidence surface 31 of the optical amplifier 3 by the first light-guiding optical system 4.

The optical amplifier 3 amplifies the laser light, which has entered the incidence surface 31, according to amplification conditions, and emits the laser beam L′, obtained by the amplified laser light, from the emission surface 32.

The laser beam L′ from the emission surface 32 of the optical amplifier 3 is focused (and/or deflected) by the second light-guiding optical system 5, so that the focused laser beam is emitted to the target object.

In the laser apparatus 200 in the above embodiment, the first light-guiding optical system 4 is utilized in order to increase the incidence efficiency of laser light from the light source section 2 to the optical amplifier 3. However, the present disclosure is not limited to this embodiment. Alternatively, the laser apparatus 200 may be configured so that the light source section 2 and the optical amplifier 3 are connected directly by using an optical fiber or the like. Further, the first light-guiding optical system 4 may be implemented by a focusing optical system including a plurality of optical elements having focusing characteristics.

### Detailed Configuration

Next, a detailed configuration of the laser apparatus 200 will be described.

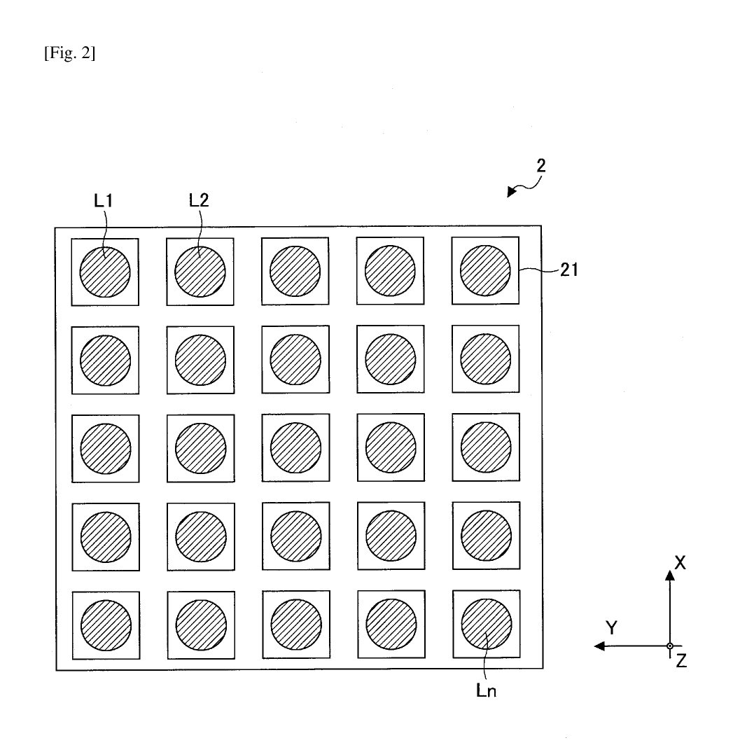

FIG. 2 illustrates a configuration of the light source section 2. The light source section 2 is implemented by a VCSEL (vertical cavity surface emitting laser) surface emitting laser array. As illustrated in FIG. 2, in the surface emitting laser array of the light source section 2, 25 laser elements 21 (or the seed lasers L1 to Ln) are arrayed in five columns and five rows in a two-dimensional formation on a surface of the light source section 2 on the +Z direction side.

Each laser element 21 (the seed laser L) serves as a seed light source or an emission point configured to output laser light. A wavelength of the laser light output from the seed laser L is approximately equal to 1060 nm. It is preferable that the seed laser L is of single mode output type.

The optical amplifier 3 serves as a laser amplifier, i.e., an optical amplification section configured to combine the laser light output from the seed lasers L1 to Ln (the laser elements 21) of the light source section 2 to emit the laser beam L′.

As illustrated in FIG. 1, the optical amplifier 3 includes three optical fiber amplifiers 33a, 33b, and 33c. Each of the optical fiber amplifiers 33a, 33b, and 33c has a core portion which is made of silica glass as a main ingredient, and a rare-earth element, such as Yb (ytterbium), is doped in the core portion as an activation material. WDM (wavelength division multiplexing) couplers 34a, 34b, and 34c which serve as excitation light coupling optical elements are respectively attached to end portions of the optical fiber amplifiers 33a, 33b, and 33c on the −Z direction side. A pair of the optical fiber amplifier 33a and the WDM coupler 34a operates as a coupling amplifier and serves as a first stage amplifier disposed in the most upstream position of the optical amplifier 3.

Similarly, a pair of the optical fiber amplifier 33b and the WDM coupler 34b operates as a second stage amplifier of the optical amplifier 3, and a pair of the optical fiber amplifier 33c and the WDM coupler 34b operates as a third stage amplifier of the optical amplifier 3.

In this embodiment, the first stage amplifier, the second stage amplifier, and the third stage amplifier are connected in series as illustrated in FIG. 1 to implement the optical amplifier 3.

Each of the WDM couplers 34a, 34b, and 34c serves as an optical multiplexer to combine a plurality of input light rays with wavelengths and waveforms, and as an optical demultiplexer to divide an input combined light beam into light rays with respective wavelengths and waveforms. After the laser light from the seed lasers L1 to Ln passes through the WDM coupler 34a disposed in the most upstream position in the −Z direction, the laser light from the seed lasers L1 to Ln is combined, and a laser beam obtained by combining the laser light enters the optical fiber amplifier 33a, so that the laser beam is amplified by the optical fiber amplifier 33a.

Each of the WDM couplers 34a, 34b, and 34c causes an excitation light P from an excitation light source 934, in addition to the laser light from the seed laser L, to enter the corresponding one of the optical fiber amplifiers 33a, 33b, and 33c based on the amplification conditions controlled by the amplification condition control unit 93.

Each of the optical fiber amplifiers 33a, 33b, and 33c amplifies the laser light having a wavelength in the vicinity of 1060 nm, which is included in a gain wavelength band, according to the induced emission arising by the excitation of Yb by the excitation light P. It is preferable that the wavelength of the excitation light P is varied depending on the type of the activation material. In this embodiment, the excitation light P having a wavelength of 975 nm which is included in the absorption band of Yb is used.

In this embodiment, the three optical fiber amplifiers 33a, 33b, and 33c are connected in series to implement the optical amplifier 3. Alternatively, the optical amplifier 3 may be implemented by at least one pair of the optical fiber amplifier and the WDM coupler to emit the laser beam L′. Further, the optical amplifier 3 may be implemented by four or more optical fiber amplifiers connected to serve as a single optical amplification section.

In addition, a main amplifier of a different type may be attached to the +Z direction side end portion of the optical fiber amplifier 33c disposed in the most downstream position in the direction of the optical axis.

Further, a WDM coupler 34d is disposed at the end of the optical amplifier 3 in the +Z direction as a separation unit to separate the excitation light P from the laser beam L′.

In this embodiment, the light source section 2 is implemented by a single VCSEL unit. Alternatively, the laser apparatus 200 may be configured to include two or more light source sections 2, and two or more optical amplifiers 3 corresponding to the light source sections 2, which are connected in parallel, and a beam combiner attached to the end portions of the optical amplifiers 3. By this configuration, it is possible to increase the output power of the laser beam L′.

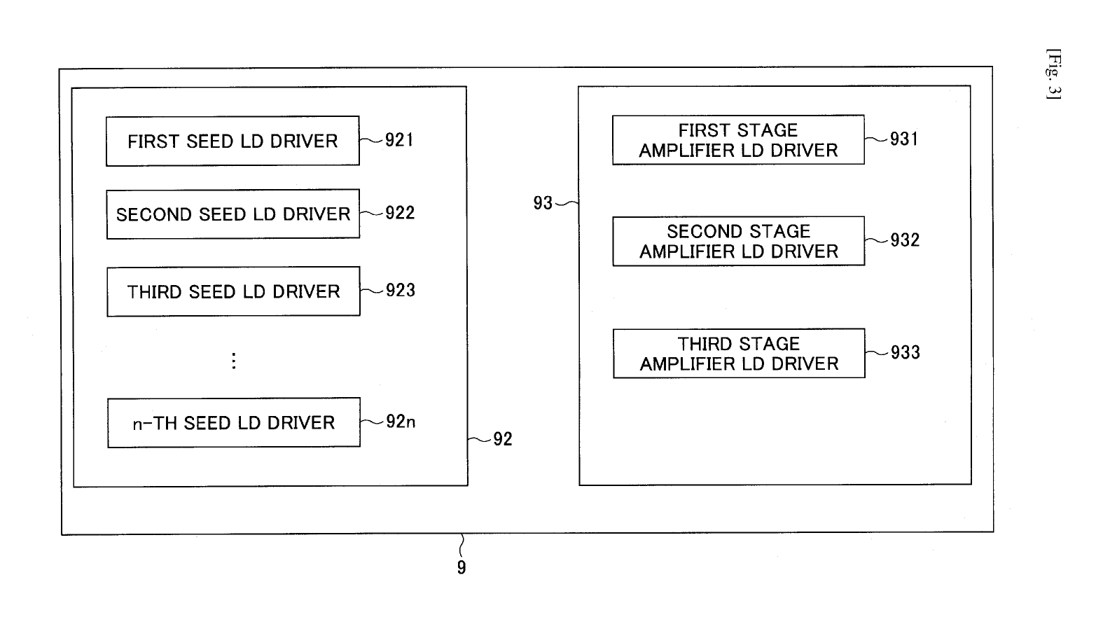

FIG. 3 illustrates a functional configuration of the control unit 9. As illustrated in FIG. 3, the amplification condition control unit 93 includes a first stage amplifier LD (laser diode) driver 931 configured to control the excitation light P being supplied to the WDM coupler 34a attached to the first stage optical fiber amplifier 33a.

The amplification condition control unit 93 includes a second stage amplifier LD driver 932 configured to control the excitation light P being supplied to the WDM coupler 34b attached to the second stage optical fiber amplifier 33b.

The amplification condition control unit 93 includes a third stage amplifier LD driver 933 configured to control the excitation light P being supplied to the WDM coupler 34c attached to the third stage optical fiber amplifier 33c.

The first stage amplifier LD driver 931, the second stage amplifier LD driver 932, and the third stage amplifier LD driver 933 may be controlled to operate independently of each other, such that the excitation light rays P from the light sources 934 are amplified based on mutually different amplification conditions to emit different excitation light rays P.

In this embodiment, the excitation light source 934 is used as the excitation LD which emits the excitation light P.

Alternatively, each of the first stage amplifier LD driver 931, the second stage amplifier LD driver 932, and the third stage amplifier LD driver 933 may be configured to emit the excitation light P according to the amplification condition. Further, the excitation light sources 934 may be provided outside the laser apparatus 200.

As illustrated in FIG. 3, the oscillating condition control unit 92 includes a first seed LD control unit 921, a second seed LD control unit 922, a third seed LD control unit 923, . . . , and an n-th seed LD control unit 92n, which are configured to control the waveforms of the laser light emitted by the seed lasers L1 to Ln (the laser elements 21), respectively.

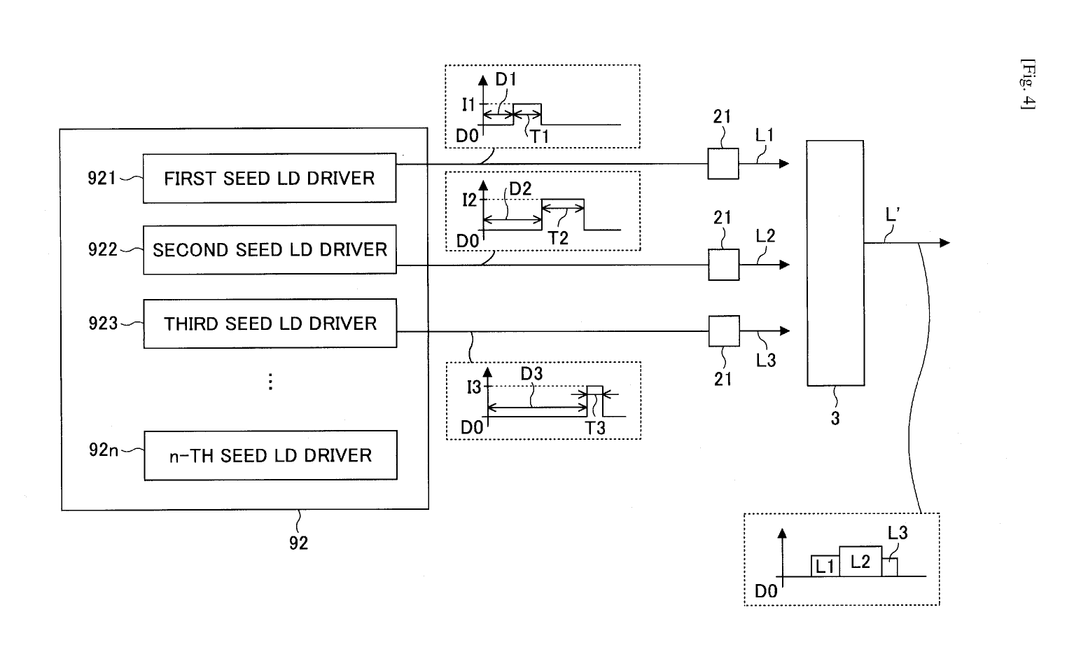

The first through n-th seed LD control units 921 to 92n operate independently of each other, but each control unit has the same function. In the following, the first seed LD control unit 921 is taken as a typical example, and a control operation of the first seed LD control unit 921 will be described with reference to FIG. 4.

The first seed LD control unit 921 functions as an arbitrary waveform generator to set up a pulse width T1 of the seed laser L1, a pulse height value I1 of the seed laser L1, and a pulse delay D1 of the seed laser L1 (which indicates a rise timing of the pulse). Each of the second through n-th seed LD control units 922 to 92n also has the same function. Hence, when the laser light from the seed lasers L1 to Ln is combined by the optical amplifier 3, the resulting laser beam L′ has a waveform that is consistent with a combined waveform of the seed lasers L1 to Ln as illustrated to FIG. 4.

The light source section 2 of the laser beam generation apparatus 200 may be implemented by either an edge emitting LD (Tocan type) or an edge emitting LD (butterfly package type). Further, the light source section 2 may be implemented by an edge emitting LD array in which a plurality of edge emitting LDs (butterfly package type) are mounted on a pulse driver substrate.

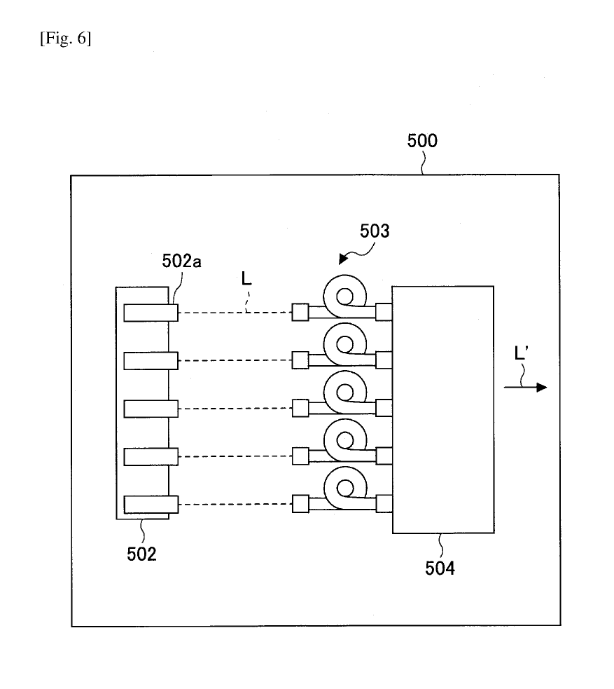

FIG. 6 illustrates a comparative example of the laser beam generation apparatus. As illustrated in FIG. 6, the comparative example is an MOPA laser apparatus 500. The MOPA laser apparatus 500 includes a seed light source 502, optical fiber amplifiers 503, and a combiner 504. In the seed light source 502, a plurality of edge emitting lasers 502a are arrayed in parallel. The optical fiber amplifiers 503 are arrayed in parallel as the optical amplification section to face the corresponding edge emitting lasers 502a.

It is difficult to bring the emission points of the edge emitting lasers 502a in close proximity, and it is difficult to attain the miniaturization of the laser apparatus 500.

Further, because bringing the emission points of the edge emitting lasers 502a in close proximity is difficult, causing the laser light rays from the seed lasers to enter a single optical fiber amplifier 503 is difficult. Hence, it is difficult for the MOPA laser apparatus 500 to carry out complicated control of the pulse waveform by the combination of the laser light rays from the seed lasers.

A conceivable method for eliminating the above problem is that the laser light rays from the seed lasers are amplified differently by the optical fiber amplifiers 503, and the combiner 504 is configured to combine the amplified laser light rays from the optical fiber amplifiers 503. However, in this case, the minor differences in performance between the optical fiber amplifiers 503 and the synchronization problem are vulnerable to deviation of the final output waveform.

It is difficult for the edge emitting lasers to output a short pulse laser beam or a multi-channel laser beam. Also, there is the problem of synchronization between the drivers. Hence, for the purpose of application to laser machining devices in the machining field or the medical field which require a high level of accuracy, a laser apparatus capable of performing highly accurate control is demanded.

As described in the foregoing, in this embodiment, the light source section 2 is implemented by the surface emitting laser array in which the surface emitting lasers (the laser elements 21) as the emission points are arrayed in a two-dimensional formation.

Generally, the edge emitting lasers require a cleavage process and it is difficult for the edge emitting lasers to output a short pulse laser beam. However, it is possible for the surface emitting lasers to output a short pulse laser beam because the surface emitting lasers are produced by utilizing a thin-film laminating process.

Further, the level of integration of the surface emitting lasers is easily increased and it is possible for the surface emitting lasers to output a multi-channel laser beam. Hence, the laser beam generation apparatus according to this embodiment provides a high level of controllability.

Further, the volume of the active region of the surface emitting laser is small, and the carriers may be sufficiently introduced by a comparatively small amount of current. The vibration at a rise timing (relaxed vibration) is prevented, thereby facilitating the short-pulse drive control.

Next, the control of an output waveform of the laser beam L′ according to this embodiment will be described.

The control unit 9 causes the oscillating condition control unit 92 to determine the oscillating conditions of each of the seed lasers L1 to Ln.

Specifically, as illustrated in FIG. 4, the oscillating condition control unit 92 is configured to set up a pulse delay of each of the seed lasers L1 to Ln by bringing the same forward or backward from an arbitrary reference time D0, and determine a combined waveform of the seed lasers L1 to Ln.

After the laser light from the seed lasers L1 to Ln is combined by the WDM coupler 34a, the combined laser light is amplified by the optical fiber amplifier 33a.

In this way, the laser apparatus 200 controls the waveform of the final output laser beam L′ with a high level of accuracy by causing the optical fiber amplifier 33a to amplify the combined laser light from the seed lasers L1 to Ln.

In this embodiment, the laser apparatus 200 includes the light source section 2 having the plurality of laser elements 21 each outputting the laser light, and the control unit 9 configured to control each of the laser elements 21 of the light source section 2.

Namely, the laser beam generation apparatus according to this embodiment (the laser apparatus 200) includes the light source section 2 having the laser elements 21 (the emission points) each outputting the laser light, and the control unit 9 configured to control each of the emission points of the light source section 2.

The laser apparatus 200 includes the optical amplifier 3 having the incidence surface 31 disposed to face the emission points of the light source section 2 in the +Z direction to receive the laser light from the seed lasers L1 to Ln, and having the emission surface 32 to emit the amplified laser light. The optical amplifier 3 is configured to combine the laser light output from the seed lasers L1 to Ln (the laser elements 21) to emit the laser beam L′. Hence, the optical amplifier 3 is configured to combine the laser light output from the emission points to emit the laser beam.

Accordingly, the laser apparatus 200 is able to control the waveform of the final output laser beam L′ with a high level of accuracy.

The laser apparatus 200 includes the optical fiber amplifiers 33a, 33b, and 33c which are connected in series to implement the optical amplifier 3.

Hence, the pulse height I of the laser light or the output power is increased gradually, and the laser light is efficiently amplified while reducing the influence on the pulse width T.

The light source section 2 is implemented by a VCSEL surface emitting laser in which the laser elements 21 are arrayed in a two-dimensional formation on the XY plane perpendicular to the optical axis of the laser light (the Z direction). The level of integration of the laser elements 21 is easily increased and it is possible for the laser apparatus 200 to control the waveform of the final output laser beam L′ with a high level of accuracy.

In this embodiment, the control unit 9 controls the seed lasers L1 to Ln of the light source section 2 to perform pulsed oscillation independently of each other.

Hence, the waveform of the final output laser beam L′ is determined by the combined waveform of the seed lasers L1 to Ln, and it is possible for the laser apparatus 200 to control the waveform of the laser beam L′ with a high level of accuracy.

### Modification

Next, a modification of the above-described embodiment will be described. In this modification, the laser apparatus 200 is configured so that only the n-th seed laser Ln among the seed lasers L1 to Ln is controlled to perform continuous oscillation (DC oscillation) instead of pulsed oscillation.

In this modification, other elements of the laser apparatus 200, which are different from the n-th seed LD control unit 92n′ configured to control the n-th seed laser Ln to perform continuous oscillation, are essentially the same as corresponding elements of the above-described embodiment and designated by the same reference signs, and a description thereof is omitted.

The n-th seed LD control unit 92n′ includes a pulse height determination unit configured to determine a pulse height In of the n-th seed laser Ln. Namely, in this modification, the n-th seed LD control unit 92n′ is configured to control the n-th seed laser Ln by setting the pulse width of the n-th seed laser Ln to infinity and setting the duty ratio thereof to 100%. At this time, the n-th seed LD control unit 92n′ serves as a continuous-oscillation control unit.

In this modification, at least one of the seed lasers L1 to Ln is controlled to perform continuous oscillation, and the incidence energy per unit time of the final output laser beam L′ is increased, and increased flexibility in controlling the waveform is provided.

The number of the seed lasers L controlled to perform continuous oscillation (DC oscillation) is not limited to one as in the above example. Alternatively, the laser apparatus 200 may be configured to control two or more seed lasers among the seed lasers L1 to Ln to perform continuous oscillation (DC oscillation) instead of pulsed oscillation.

The present disclosure is not limited to the above-described embodiments, but various variations and modifications may be made without departing from the scope of the present disclosure.

For example, the laser apparatus 200 in the above-described embodiment may be applied to a pulsed laser machining device utilized for metalworking, and may be applied to medical equipment, such as a laser surgical unit. Further, the laser apparatus 200 may be applied to various devices, including a spectroscopic device, an analytical device, a sensing device, and a LIDAR (laser imaging detection and ranging) device.

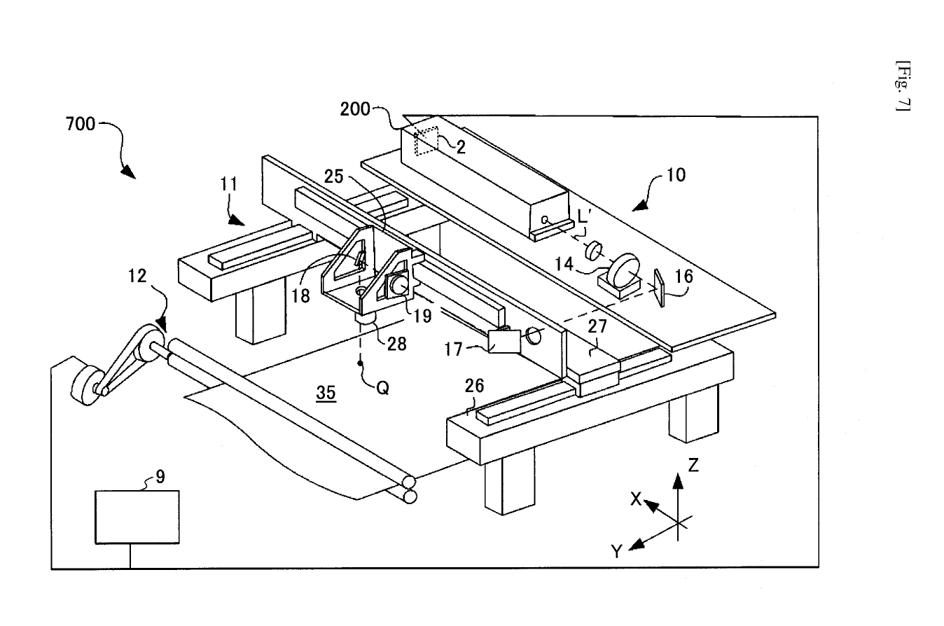

Next, an example in which the laser apparatus 200 is applied to a laser machining device will be described with reference to FIG. 7. In FIG. 7, the elements which are essentially the same as corresponding elements in the above-described embodiments are designated by the same reference signs, and a description thereof is omitted.

As illustrated in FIG. 7, a laser machining device 700 includes a laser output section 10 in which the laser apparatus 200 is disposed, a laser scanning section 11, a work transport section 12, and the control unit 9. The laser machining device 700 further includes a plurality of reflection mirrors 16, 17, and 18 configured to form an optical path of the laser beam L′ output from the laser output section 10, and a focusing lens (fθ lens) 28 configured to convert the laser beam L′ from the reflection mirror 18 into a converging laser beam at an emission position Q.

The laser output section 10 includes the laser apparatus 200 and a beam expander 14 configured to change the diameter of the laser beam L′ output from the laser apparatus 200.

The laser scanning section 11 is implemented by a scanning unit which is supported to be movable on an XY plane by using a main-scanning direct-acting stage 27 and a sub-scanning direct-acting stage 26 (which will be described later) and configured to move the emission position Q of the laser beam L′ output from the laser output section 10 on the XY plane. The laser scanning section 11 includes a diffraction optical element 19 disposed at an end portion on the incident side of the laser beam L′.

The diffraction optical element 19 is configured to convert an intensity distribution and a spot profile of the laser beam L′ at an image formation position, and is capable of setting up the top hat distribution and the rectangular shape of the laser beam L′ arbitrarily.

The laser scanning section 11 is supported by a carriage 25 mounted on the main-scanning direct-acting stage 27, so that the laser scanning section 11 is movable in a main scanning direction that is the X-axis direction. The main-scanning direct-acting stage 27 is supported by the sub-scanning direct-acting stage 26, so that the main-scanning direct-acting stage 27 is movable in a sub-scanning direction that is the Y-axis direction.

The work transport section 12 is implemented by a pair of transport rollers, and these transport rollers are configured to transport a work 35 (target object) while sandwiching the work 35 between the transport rollers. The control unit 9 is configured to control the light source section 2 to perform the pulsed oscillation of the seed lasers L1 to Ln independently of each other.

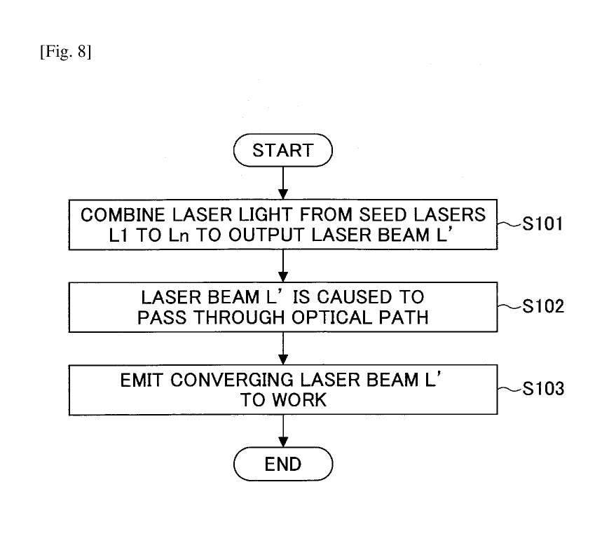

Next, a laser machining method for machining the work 35 (target object) by the above-described laser machining device 700 will be described with reference to FIG. 8.

The control unit 9 controls the light source section 2 to perform the pulsed oscillation of the seed lasers L1 to Ln independently of each other. As previously described with reference to FIG. 1, the optical amplifier 3 combines the laser light from the seed lasers L1 to Ln as the laser beam L′, and the laser output section 10 outputs the combined laser light as the laser beam L′ (step S101). The step S101 is a step of combining the laser light from the seed lasers L1 to Ln which are controlled to perform the pulsed oscillation independently of each other, and outputting the combined laser light as the laser beam L′.

The laser beam L′ output from the laser output section 10 is reflected by the reflection mirror 16 fixed to the laser output section 10, and reflected by the reflection mirror 17 on the main-scanning direct-acting stage 27, and further reflected by the reflection mirror 18 fixed to the laser scanning section 11, and then enters the fθ lens 28 (step S102).

The fθ lens 28 converts the incoming laser beam L′ into the converging laser beam L′, and the laser machining device 700 emits the converging laser beam L′ to the work 35 at the emission position Q on the work 35 (step S103). The step S103 is a step of machining the work 35 by the converging laser beam.

The emission position Q may be changed to another position by moving the laser scanning section 11 on the XY plane according to the type of machining on the work 35.

By applying the laser apparatus 200 to the laser machining device 700, it is possible for the laser machining device 700 to perform the laser machining process based on machining conditions suitable for the type of the work 35 being machined or for each machining portion. Further, it is possible for the laser machining device 700 to perform the laser machining process based on complicated machining conditions, such as machining conditions in which a non-heating process and a heating process are combined.

For example, in metalworking, it is possible for the laser machining device 700 to form dimples on the work 35 in the non-heating process (e.g., a laser ablation process) by performing the short pulsed oscillation, and smooth the dimpled surface of the work 35 in the heating process (e.g., a melting process) by performing the continuous oscillation.

In this embodiment, the control unit 9 is configured to control the seed lasers L1 to Ln to perform the pulsed oscillation. Alternatively, the control unit 9 may be configured to control at least one of the seed lasers L1 to Ln to perform the continuous oscillation (DC oscillation), instead of the pulsed oscillation.

All examples and conditions described in the foregoing are to be construed as being without limitation to such specifically recited examples and conditions, nor does the organization of such examples in the specification relate to a showing of superiority or inferiority of the invention.

The present application is based upon and claims the benefit of priority of Japanese Patent Application No. 2015-222048, filed on Nov. 12, 2015, and Japanese Patent Application No. 2016-181685, filed on Sep. 16, 2016, the contents of which are incorporated herein by reference in their entirety.

### REFERENCE SIGNS LIST

2 light source section
3 optical amplifier
9 control unit
21 emission point (laser element)
31 incidence surface
32 emission surface
35 work (target object)
92 oscillating condition control unit
93 amplification condition control unit
92n′ continuous-oscillation control unit (n-th seed LD control unit)
L1 to Ln seed lasers
L′ laser beam
200 laser beam generation apparatus (laser apparatus)
700 laser machining device
S101 combining step
S103 machining step

1-10. (canceled)

11: A laser beam generation apparatus comprising:
a light source section including a surface emitting laser array in which a plurality of seed lasers, each emitting laser light, are arrayed in a two-dimensional formation on a surface of the light source section;
an optical amplification section disposed to face the seed lasers of the light source section and configured to amplify the laser light emitted by the seed lasers and received at an incidence surface to output the amplified laser light from an emission surface; and
a control unit configured to control the seed lasers of the light source section independently of each other,
wherein the optical amplification section is configured to combine the laser light emitted by the seed lasers and output the combined laser light as a laser beam.

12: The laser beam generation apparatus according to claim 11, wherein the optical amplification section comprises a plurality of optical amplifiers which are connected in series.

13: The laser beam generation apparatus according to claim 11, wherein the light source section comprises a plurality of surface emitting lasers which are arrayed in a two-dimensional formation on a surface perpendicular to a direction of an optical axis of the laser light.

14: The laser beam generation apparatus according to claim 11, wherein the control unit is configured to control the seed lasers of the light source section to perform pulsed oscillation independent of each other.

15: The laser beam generation apparatus according to claim 11, wherein the control unit is configured to control at least one of the seed lasers of the light source section to perform continuous oscillation, and configured to control other seed lasers to perform pulsed oscillation.

16: The laser beam generation apparatus according to claim 11, wherein the optical amplification section comprises an optical fiber amplifier.

17: The laser beam generation apparatus according to claim 14, wherein the control unit is configured to set up a pulse width of each of the seed lasers which are controlled to perform pulsed oscillation.

18: The laser beam generation apparatus according to claim 14, wherein the control unit is configured to set up a pulse height value of each of the seed lasers which are controlled to perform pulsed oscillation.

19: The laser beam generation apparatus according to claim 14, wherein the control unit is configured to set up a pulse delay of each of the seed lasers controlled to perform pulsed oscillation, by bringing the pulse delay forward or backward from an arbitrary reference time.

20: The laser beam generation apparatus according to claim 11, wherein the laser light emitted by each of the seed lasers is of single mode output type.

21: A laser machining device comprising:
a laser beam generation apparatus, the laser beam generation apparatus including:
a light source section including a surface emitting laser array in which a plurality of seed lasers, each emitting laser light, are arrayed in a two-dimensional formation on a surface of the light source section;
an optical amplification section disposed to face the seed lasers of the light source section and configured to amplify the laser light emitted by the seed lasers and received at an incidence surface to output the amplified laser light from an emission surface; and
a control unit configured to control the seed lasers of the light source section independently of each other,
wherein the optical amplification section is configured to combine the laser light emitted by the seed lasers and output the combined laser light as a laser beam, and
wherein the laser machining device is configured to machine a target object by the laser beam output from the laser beam generation apparatus.

22: The laser machining device according to claim 21, wherein the control unit is configured to control the seed lasers of the light source section to perform pulsed oscillation independently of each other.

23: The laser machining device according to claim 21, wherein the control unit is configured to control at least one of the seed lasers of the light source section to perform continuous oscillation, and configured to control other laser beams to perform pulsed oscillation.

24: A laser machining method comprising:
combining laser light emitted by a plurality of seed lasers which are controlled to perform pulsed oscillation independently of each other;
outputting the combined laser light as a laser beam; and
machining a target object by the laser beam.

25: The laser machining method according to claim 24, wherein at least one of the seed lasers is controlled to perform continuous oscillation, and other seed lasers are controlled to perform the pulsed oscillation, and
the combining includes combining the laser light emitted by the other seed lasers and laser light emitted by the at least one of the seed lasers.
